(19) United States
(12) Patent Application Publication
(10) Pub. No.: US 2011/0079815 A1
(43) Pub. Date: Apr. 7, 2011

(54) ORGANIC ELECTROLUMINESCENCE DEVICE AND MANUFACTURING METHOD THEREOF

(76) Inventors: Akiyoshi YAMADA, Ichikawa-shi (JP); Yuuji Nakamura, Fukaya-shi (JP)

(21) Appl. No.: 12/882,760

(22) Filed: Sep. 15, 2010

(30) Foreign Application Priority Data
Oct. 5, 2009 (JP) 2009-231821

(51) Int. Cl. H01L 51/50; H01L 33/00

(52) U.S. Cl. 257/99; 438/22; 257/E51.018; 257/E33.001

(57) ABSTRACT

According to one embodiment, an organic EL device includes an insulating substrate, a pixel electrode disposed above the insulating substrate, an organic layer disposed on the pixel electrode, a counter-electrode disposed on the organic layer, at least one of a first recess portion in which the organic layer and the counter-electrode are missing on the pixel electrode, and a second recess portion in which the counter-electrode is missing on the organic layer, and a protection film covering the counter-electrode and the at least one of the first recess portion and the second recess portion.

### CROSS-REFERENCE TO RELATED APPLICATIONS

This application is based upon and claims the benefit of priority from Japanese Patent Application No. 2009-231821, filed Oct. 5, 2009; the entire contents of which are incorporated herein by reference.

### FIELD

Embodiments described herein relate generally to an organic electroluminescence device and a manufacturing method thereof.

### BACKGROUND

In recent years, display devices using organic electroluminescence (EL) elements have vigorously been developed, which have features of self-emission, a high response speed, a wide viewing angle and a high contrast, and which can realize further reduction in thickness and weight.

For example, Jpn. Pat. Appln. KOKAI Publication No. 2004-362912 discloses a technique relating to an organic EL element in which a first electrode, an organic EL layer and a second electrode are successively stacked on a glass substrate. In this technique, a part other than a surface where the first electrode, organic EL layer and second electrode neighbor each other is covered with a protection film, and the film thickness from the surface of the first electrode to the outer surface of the protection film in the part where a foreign matter is not present on the first electrode is set to be greater than the size of the foreign matter which is present on the first electrode.

### BRIEF DESCRIPTION OF THE DRAWINGS

FIG. 1 is a plan view which schematically shows the structure of an organic EL display device according to an embodiment;

FIG. 2 is a schematic cross-sectional view of an array substrate including an organic EL element of the organic EL display device shown in FIG. 1;

FIG. 3 is a cross-sectional view which schematically shows a main part including an emission part and a non-emission part of the organic EL element in the embodiment;

FIG. 4 is a view for describing a manufacturing method of the organic EL element in the embodiment, and is a view for describing an example in which a first recess portion is formed as a non-emission part;

FIG. 5 is a view for describing a manufacturing method of the organic EL element in the embodiment, and is a view for describing an example in which a second recess portion is formed as a non-emission part;

FIG. 6 is a view for describing a dry wash process which is applied to the embodiment;

FIG. 7 is a view which schematically shows the structure of a wash gun which is applied to the dry wash process of the embodiment; and

FIG. 8 is a schematic view for describing the dry wash process of the embodiment.

### DETAILED DESCRIPTION

In general, according to one embodiment, there is provided an organic EL device comprising: an insulating substrate; a pixel electrode disposed above the insulating substrate; an organic layer disposed on the pixel electrode; a counter-electrode disposed on the organic layer; at least one of a first recess portion in which the organic layer and the counter-electrode are missing on the pixel electrode, and a second recess portion in which the counter-electrode is missing on the organic layer; and a protection film covering the counter-electrode and said at least one of the first recess portion and the second recess portion.

In general, according to another embodiment, there is provided an organic EL device comprising: an insulating substrate; an organic EL element disposed above the insulating substrate and including an emission part which emits light, and a recess part which emits no light and has an area of less than 10% when an area of the emission part is set to be 100%; and a protection film covering the organic EL element.

In general, according to another embodiment, there is provided a manufacturing method of an organic EL device, comprising: forming a pixel electrode above an insulating substrate; forming an organic layer on the pixel electrode; forming a counter-electrode on the organic layer; and performing dry wash which jets toward a surface of a process substrate, on which the counter-electrode is already formed, particulate matter which is sublimated after colliding with the surface of the process substrate.

Embodiments will now be described in detail with reference to the accompanying drawings. In the drawings, structural elements having the same or similar functions are denoted by like reference numerals, and an overlapping description is omitted.

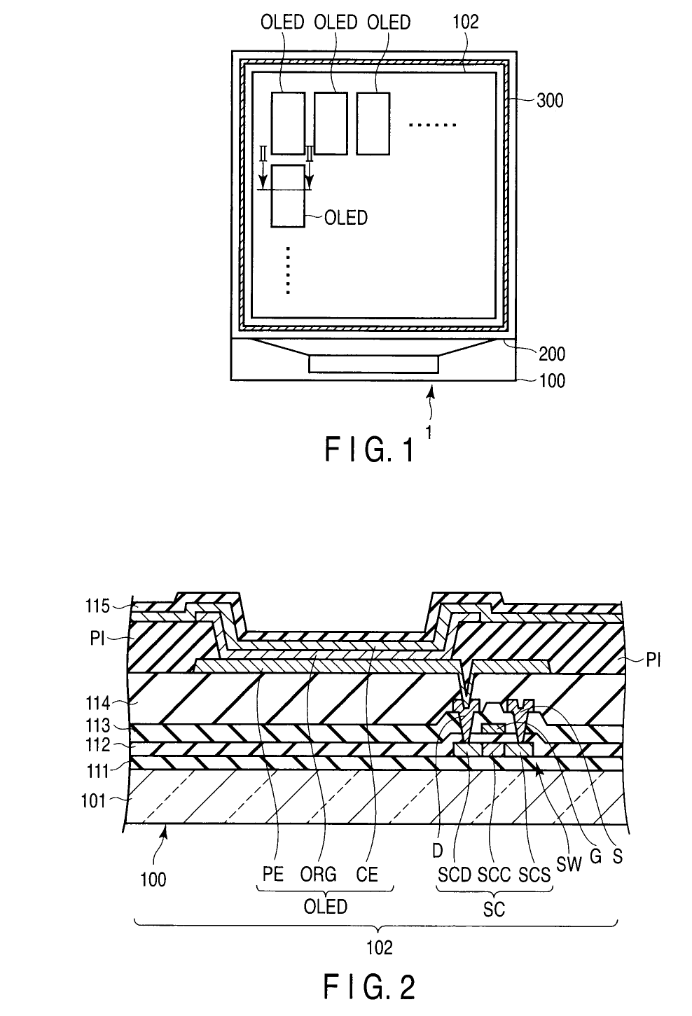

FIG. 1 is a plan view which schematically shows the structure of an organic EL display device, as an example of an organic EL device, which adopts an active matrix driving method.

Specifically, the organic EL display device includes a display panel 1. The display panel 1 includes an array substrate 100 and a sealing substrate 200. The array substrate 100 includes a plurality of matrix-arrayed organic EL elements OLED in a substantially rectangular active area 102 which displays an image. In the active area 102, the sealing substrate 200 is opposed to the organic EL elements OLED which are included in the array substrate 100. The sealing substrate 200 is a light-transmissive insulating substrate such as a glass substrate or a plastic substrate.

The array substrate 100 and sealing substrate 200 are attached to each other via a sealant 300 which is formed in a frame shape surrounding the active area 102. The sealant 300 is formed of, e.g. a resin material or frit glass.

FIG. 2 is a cross-sectional view of the array substrate 100 including the organic EL element OLED of the organic EL display device shown in FIG. 1.

The array substrate 100 includes a light-transmissive insulating substrate 101, such as a glass or plastic substrate, and a switching element SW and an organic EL element OLED which are disposed above the insulating substrate 101.

A first insulation film 111 is disposed on the insulating substrate 101. The first insulation film 111 extends over almost the entirety of the active area 102. The first insulation film 111 is formed of, for example, an inorganic compound such as silicon oxide or silicon nitride.

A semiconductor layer SC of the switching element SW is disposed on the first insulation film 111. The semiconductor layer SC is formed of, e.g. polysilicon. In the semiconductor layer SC, a source region SCS and a drain region SCD are formed, with a channel region SCC being interposed therebetween.

The semiconductor layer SC is covered with a second insulation film 112. The second insulation film 112 is also disposed on the first insulation film 111. The second insulation film 112 extends over almost the entirety of the active area 102. The second insulation film 112 is formed of, for example, an inorganic compound such as silicon oxide or silicon nitride.

A gate electrode G of the switching element SW is disposed on the second insulation film 112 immediately above the channel region SCC. In this example, the switching element SW is a top-gate type p-channel thin-film transistor. The gate electrode G is covered with a third insulation film 113. The third insulation film 113 is also disposed on the second insulation film 112. The third insulation film 113 extends over almost the entirety of the active area 102. The third insulation film 113 is formed of, for example, an inorganic compound such as silicon oxide or silicon nitride.

A source electrode S and a drain electrode D of the switching element SW are disposed on the third insulation film 113. The source electrode S is put in contact with the source region SCS of the semiconductor layer SC. The drain electrode D is put in contact with the drain region SCD of the semiconductor layer SC. The gate electrode G, source electrode S and drain electrode D of the switching element SW are formed of an electrically conductive material such as molybdenum (Mo), tungsten (W), aluminum (Al) or titanium (Ti).

The source electrode S and drain electrode D are covered with a fourth insulation film 114. The fourth insulation film 114 is also disposed on the third insulation film 113. The fourth insulation film 114 extends over almost the entirety of the active area 102. The fourth insulation film 114 is formed of an organic compound such as an ultraviolet-curing resin or a thermosetting resin, or an inorganic compound such as silicon nitride.

A pixel electrode PE, which constitutes the organic EL element OLED, is disposed on the fourth insulation film 114. The pixel electrode PE is electrically connected to the drain electrode D of the switching element SW. The pixel electrode PE corresponds to, e.g. an anode. The structure of the pixel electrode PE is not specifically limited. The pixel electrode PE may have a two-layer structure in which a reflective layer and a transmissive layer are stacked, or the pixel electrode PE may have a single-layer structure of a reflective layer or a transmissive layer. Besides, the pixel electrode PE may have a multilayer structure of three or more layers. The reflective layer is formed of a light-reflective electrically conductive material, such as silver (Ag) or aluminum (Al). The transmissive layer is formed of a light-transmissive electrically conductive material, such as indium tin oxide (ITO) or indium zinc oxide (IZO). In the case where the organic EL element OLED is of a top emission type which emits light from the sealing substrate 200 side, the pixel electrode PE includes at least the reflective layer.

A partition wall PI is disposed on the fourth insulation film 114. The partition wall PI is disposed along the peripheral edge of the pixel electrode PE. The partition wall PI overlaps a part of the pixel electrode PE. The partition wall PI is formed of an insulating material, for instance, an organic compound such as an ultraviolet-curing resin or a thermosetting resin, or an inorganic compound of various kinds, such as silicon nitride. The organic EL element OLED is surrounded and isolated by the partition wall PI.

An organic layer ORG, which constitutes the organic EL element OLED, is disposed on the pixel electrode PE. The organic layer ORG includes at least a light emission layer, and may further include a hole injection layer, a hole transport layer, an electron injection layer, and an electron transport layer. The organic layer ORG may be a continuous film extending over almost the entirety of the active area 102. At least a part of the organic layer ORG may be formed of a fluorescent material, or may be formed of a phosphorescent material.

A counter-electrode CE, which constitutes the organic EL element OLED, is disposed on the organic layer ORG. In this example, the counter-electrode CE corresponds to a cathode. The counter-electrode CE is a continuous film which extends over almost the entirety of the active area 102, and covers the organic layer ORG and the partition wall PI.

The counter-electrode CE is formed of, e.g. a semi-transmissive layer. The semi-transmissive layer is formed of an electrically conductive material such as magnesium (Mg)-silver (Ag). The counter-electrode CE may have a two-layer structure in which a semi-transmissive layer and a transmissive layer are stacked, or the counter-electrode CE may have a single-layer structure of a transmissive layer or a semi-transmissive layer. The transmissive layer may be formed of a light-transmissive, electrically conductive material, such as ITO or IZO. In the case where the organic EL element OLED is of a bottom emission type which emits light from the insulating substrate 101 side, the counter-electrode CE includes at least a reflective layer or a semi-transmissive layer.

A protection film 115 is disposed on the counter-electrode CE. The protection film 115 extends over almost the entirety of the active area 102. Specifically, the protection film 115 covers the organic EL element OLED, and extends to an area immediately above the partition wall PI disposed around the organic EL element OLED. The protection film 115 is formed of a material which is light-transmissive and is hardly permeable to moisture, for example, an inorganic compound such as a silicon nitride or silicon oxynitride. In short, the protection film 115 functions as a moisture barrier film which prevents permeation of moisture to the organic EL element OLED.

The above-described first insulation film 111, second insulation film 112, third insulation film 113, fourth insulation film 114 and protection film 115 may extend not only over the active area 102, but also over a peripheral area 104 (not shown).

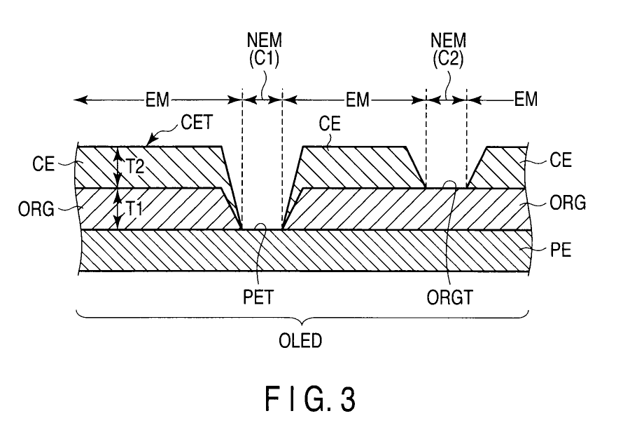

FIG. 3 is a cross-sectional view which schematically shows a main part of the organic EL element in the embodiment. FIG. 3 shows the cross-sectional structure of the organic EL element OLED which is located on the inside surrounded by the partition wall (not shown), and the depiction of the structure which is not necessary for the description is omitted.

The above-described organic EL element OLED includes an emission part EM and a non-emission part NEM. The emission part EM corresponds to a region in which the pixel electrode PE, organic layer ORG and counter-electrode CE are stacked. The emission part EM emits light when an electric current flows between the pixel electrode PE and the counter-electrode CE. On the other hand, the non-emission part NEM emits no light when an electric current flows between the pixel electrode PE and the counter-electrode CE.

The non-emission part NEM corresponds to a recess portion which is recessed from a top surface CET of the counter-electrode CE. For example, the non-emission part NEM is a first recess portion C1 in which the organic layer ORG and counter-electrode CE on the pixel electrode PE are missing, or a second recess portion C2 in which the counter-electrode CE on the organic layer ORG, which is stacked on the pixel electrode PE, is missing.

Specifically, in the first recess portion Cl, a top surface PET of the pixel electrode PE is exposed and is recessed from the top surface CET of the counter-electrode CE by a thickness corresponding to the total of a film thickness T1 of the organic layer ORG and a film thickness T2 of the counter-electrode CE. The film thickness T1 corresponds to the distance between the top surface PET of the pixel electrode PE and a top surface ORGT of the organic layer ORG. The film thickness T2 corresponds to the distance between the top surface ORGT of the organic layer ORG and the top surface CET of the counter-electrode CE. In the second recess portion C2, the top surface ORGT of the organic layer ORG is exposed and is recessed from the top surface CET of the counter-electrode CE by a thickness corresponding to the total of the film thickness T2 of the counter-electrode CE.

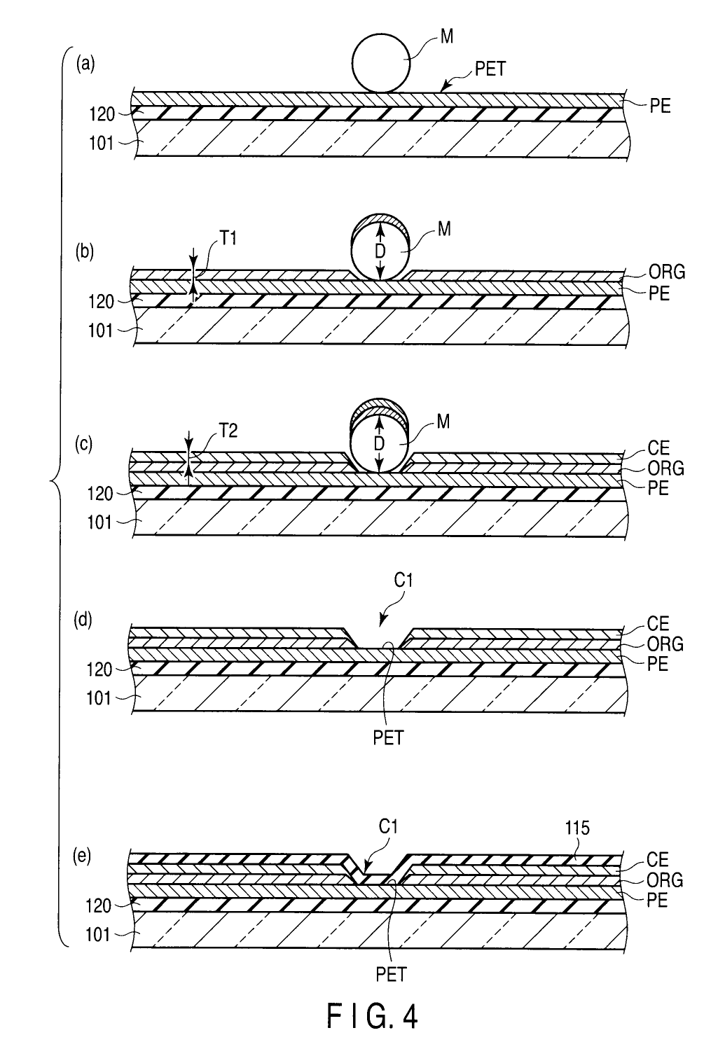

Next, referring to FIG. 4, a description is given of a manufacturing method of the organic EL element OLED shown in FIG. 3. An example in which the first recess portion C1 is formed as the non-emission part NEM is described.

To start with, as shown in part (a) of FIG. 4, the first insulation film 111, second insulation film 112, third insulation film 113, fourth insulation film 114 and switching element SW are formed on the insulating substrate 101, and then the pixel electrode PE is formed. Further, the partition wall PI is formed. In FIG. 4, the first insulation film 111, second insulation film 112, third insulation film 113 and fourth insulation film 114, which are disposed between the insulating substrate 101 and the pixel electrode PE, are generally depicted as an insulation film 120, and the depiction of the switching element SW and partition wall PI is omitted. Part (a) of FIG. 4 shows the state in which foreign matter M is present on the pixel electrode PE. Such foreign matter M adheres to the top surface PET of the pixel electrode PE after the formation of the pixel electrode PE and before the formation of the organic layer ORG.

Subsequently, as shown in part (b) of FIG. 4, the organic layer ORG is formed on the pixel electrode PE. At this time, the organic layer ORG is formed on the pixel electrode PE and on the foreign matter M which is present on the pixel electrode PE, while the organic layer ORG is not formed on the pixel electrode PE at which the foreign matter M is present. In other words, the pixel electrode PE in the vicinity of the foreign matter M is not covered with the organic layer ORG, and is exposed from the organic layer ORG. In the meantime, the film thickness T1 of the organic layer ORG is less than the size (e.g. diameter D) of the foreign matter M.

Then, as shown in part (c) of FIG. 4, the counter-electrode CE is formed on the organic layer ORG. At this time, the counter-electrode CE is formed on the organic layer ORG, and on the organic layer ORG which is present on the foreign matter M, while the counter-electrode CE is not formed on the pixel electrode PE at which the foreign matter M is present. In other words, the pixel electrode PE in the vicinity of the foreign matter M is not covered with the organic layer ORG or the counter-electrode CE, and is exposed from the counter-electrode CE. In the meantime, the film thickness T2 of the counter-electrode CE is less than the size (e.g. diameter D) of the foreign matter M.

Thereafter, as shown in part (d) of FIG. 4, the surface, on which the counter-electrode CE is already formed, is dry-washed. The dry wash will be described later in detail. Part (d) of FIG. 4 shows the state in which the foreign matter is removed from the pixel electrode PE by the dry wash. At the location where the foreign matter has been removed, neither the organic layer ORG nor the counter-electrode CE is formed, and the top surface PET of the pixel electrode PE is exposed and the first recess portion C1 is formed.

Following the above, as shown in part (e) of FIG. 4, the protection film 115, which covers the counter-electrode CE, is formed by, e.g. plasma CVD, after the dry wash. The protection film 115 is disposed on the counter-electrode CE, and covers the first recess portion C1. In other words, at the first recess portion C1, the protection film 115 is in contact with the top surface PET of the pixel electrode PE.

According to this manufacturing method, the foreign matter M adhering to the pixel electrode PE is removed before the protection film 115 is formed. Thus, the first recess portion C1, in which the organic layer ORG and counter-electrode CE on the pixel electrode PE are missing, is surely covered with the protection film 115, as well as the organic EL element OLED. Therefore, without the influence of the foreign matter M, the degradation of the organic EL element OLED due to moisture can be suppressed.

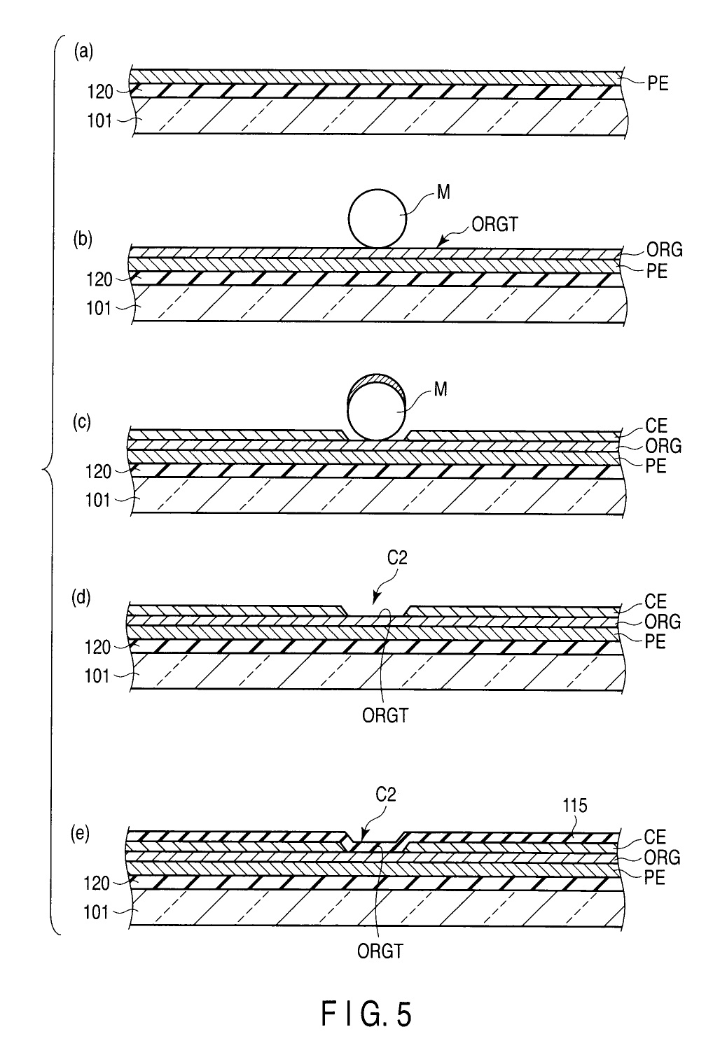

Next, referring to FIG. 5, a description is given of an example in which the second recess portion C2 is formed as the non-emission part NEM in the manufacturing process of the organic EL element OLED shown in FIG. 3. The same structural parts as in the example shown in FIG. 4 are denoted by like reference numerals, and a detailed description is omitted.

To start with, as shown in part (a) of FIG. 5, the first insulation film 120 and the switching element SW (not shown) are formed on the insulating substrate 101, and then the pixel electrode PE is formed. Further, the partition wall PI (not shown) is formed.

Subsequently, as shown in part (b) of FIG. 5, the organic layer ORG is formed on the pixel electrode PE. Part (b) of FIG. 5 shows the state in which foreign matter M is present on the organic layer ORG. Such foreign matter M adheres to the top surface ORGT of the organic layer ORG after the formation of the organic layer ORG and before the formation of the counter-electrode CE.

Then, as shown in part (c) of FIG. 5, the counter-electrode CE is formed on the organic layer ORG. At this time, the counter-electrode CE is formed on the organic layer ORG, and on the foreign matter M which is present on the organic layer ORG, while the counter-electrode CE is not formed on the organic layer ORG at which the foreign matter M is present. In other words, the organic layer ORG in the vicinity of the foreign matter M is not covered with the counter-electrode CE, and is exposed from the counter-electrode CE.

Thereafter, as shown in part (d) of FIG. 5, the surface, on which the counter-electrode CE is already formed, is dry-washed. Part (d) of FIG. 5 shows the state in which the foreign matter is removed from the organic layer ORG by the dry wash. At the location where the foreign matter has been removed, the counter-electrode CE is not formed, and the top surface ORGT of the organic layer ORG is exposed and the second recess portion C2 is formed.

Following the above, as shown in part (e) of FIG. 5, the protection film 115, which covers the counter-electrode CE, is formed by, e.g. plasma CVD, after the dry wash. The protection film 115 is disposed on the counter-electrode CE, and covers the second recess portion C2. In other words, at the second recess portion C2, the protection film 115 is in contact with the top surface ORGT of the organic layer ORG.

According to this manufacturing method, the foreign matter M adhering to the organic layer ORG is removed before the protection film 115 is formed. Thus, the second recess portion C2, in which the counter-electrode CE on the organic layer ORG is missing, is surely covered with the protection film 115, as well as the organic EL element OLED. Therefore, without the influence of the foreign matter M, the degradation of the organic EL element OLED due to moisture can be suppressed.

In the meantime, the average size of foreign matter is about 1 μm to 5 μm in diameter, and is much smaller than the size of the pixel electrode PE. Thus, even if there is the non-emission part NEM which is formed of the first recess portion C1 or second recess portion C2 due to the foreign matter, the area of the non-emission part NEM is much smaller than the area of the emission part EM. When the area of the emission part EM is set to be 100%, if the area of the non-emission part NEM is less than 10%, the non-emission part NEM is hardly visually recognized, and the emission luminance of the organic EL element OLED is little affected.

As an example, assume the case in which the organic EL element OLED includes an emission part EM of a rectangular shape with a short side of 30 μm and a long side of 140 μm. In this case, when the area occupied by foreign matter is 20 μm², the presence of spherical foreign matter with a diameter of about 5 μm is assumed. At this time, the area of the emission part EM is 4120 μm² (=30×140−20), and the area (20 μm²) of the non-emission part NEM due to the foreign matter is less than 10% of the area of the emission part EM.

As another example, assume the case in which the organic EL element OLED includes an emission part EM of a rectangular shape with a short side of 10 μm and a long side of 60 μm. In this case, when the area occupied by foreign matter is 20 μm², the presence of spherical foreign matter with a diameter of about 5 μm is assumed. At this time, the area of the emission part EM is 580 μm² (=10×60−20), and the area (20 μm²) of the non-emission part NEM due to the foreign matter is less than 10% of the area of the emission part EM.

In the meantime, such non-emission parts NEM are visually confirmed.

If the dry wash as in the present embodiment is not performed before the formation of the protection film 115, foreign matter is present on the pixel electrode PE or the organic layer ORG. If the protection film 115 is formed in the state in which the foreign matter is present, it is difficult to completely cover the foreign matter, depending on the size of the foreign matter. Moisture may enter the organic EL element OLED from a crack occurring in the protection film 115, leading to degradation of the organic EL element OLED. In particular, in the case where the protection film 115 is formed of an inorganic compound such as silicon nitride by plasma CVD, if the thickness of the protection film 115 is increased to such a degree as to cover the foreign matter, the time necessary for forming the protection film 115 would increase, leading to an increase in manufacturing cost.

Taking this into account, in the present embodiment, the dry wash is performed before the formation of the protection film 115, thereby removing the foreign matter which is present on the pixel electrode PE or the organic layer ORG. Thus, the organic EL element OLED including the emission part EM and non-emission part NEM is covered with the protection film 115. Therefore, the organic EL element OLED can be protected from moisture.

Next, the dry wash, which is applied to the embodiment, is described.

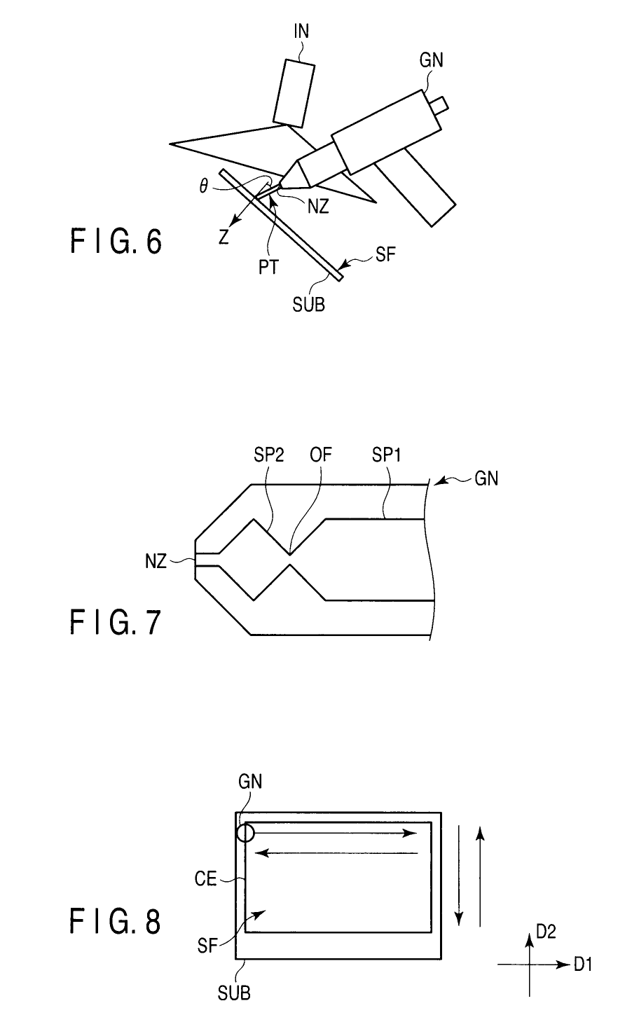

FIG. 6 is a view for describing a dry wash process.

In the dry wash which is applied to the embodiment, use is made of a wash gun GN which jets particulate matter PT. The particulate matter PT, which is jetted from the wash gun GN, is sublimated after colliding with a process substrate SUB. For example, in an inactive atmosphere of, e.g. moisture-free nitrogen gas, the wash gun GN is disposed toward a surface SF of the process substrate SUB. At this time, the distance from a nozzle NZ of the wash gun GN to the process substrate SUB is set at, e.g. about 10 mm.

The wash gun GN jets the particulate matter PT, together with an inert gas, to the surface SF of the process substrate SUB, thereby removing foreign matter from the surface SF of the process substrate SUB. The amount of jet is set at, e.g. 60 g/min per unit area. The jetted particulate matter PT is kept in a solid state until the particulate matter PT collides with the process substrate SUB. After the particulate matter PT collides with the process substrate SUB, the particulate matter PT is sublimated. Thus, the particulate matter PT does not adhere or remain on the surface SF of the process substrate SUB.

In the example shown in FIG. 6, in order to prevent electrification of the process substrate SUB while the wash gun GN jets the particulate matter PT and washes the surface SF of the process substrate SUB, it is desirable to perform de-electrification by using a soft X-ray ionizer.

In addition, an exhaust mechanism for exhausting the gas of sublimated particulate matter PT may be provided.

In order to effectively remove the foreign matter, it is desirable that the wash gun GN be disposed with an inclination to a normal line Z of the process substrate SUB. For example, the angle θ of the direction, in which the wash gun GN jets the particulate matter PT, relative to the normal line Z of the process substrate SUB is 45° to 60°. In other words, the direction, in which the particulate matter PT is jetted toward the process substrate SUB is a direction inclined to the normal line Z of the process substrate SUB.

Preferably, the dry wash should be performed before the formation of the organic layer ORG, before the formation of the counter-electrode CE, and before the formation of the protection film 115, respectively. The dry wash is performed, at least, immediately before the formation of the protection film 115. In the case where the organic layer ORG is formed as a multilayer structure of thin films such as a light emission layer, a hole transport layer and an electron transport layer, the above-described dry wash may be performed before the formation of each of the thin films. Even if the dry wash, which has been described in the embodiment, is performed immediately after the formation of the organic layer ORG, damage to the organic layer ORG can be suppressed since the dry wash is a washing method which requires no moisture.

By performing this dry wash, the foreign matter is removed and the trace of the foreign matter is covered with the protection film 115. Thus, the organic EL device having the structure with high sealing properties can be obtained.

In the present embodiment, as the method of dry wash, use is made of a method of CO₂ wash, which can remove foreign matter on the order of μm or more. The CO₂ wash employs, as the particulate matter PT, carbon dioxide particles in which carbon dioxide is coagulated. Specifically, in the CO₂ wash, the carbon dioxide particles, which are in a fine-particle phase, are made to collide with the process substrate SUB, thereby removing the foreign matter from the surface SF of the process substrate SUB. Since the carbon dioxide particles are sublimated and made into carbon dioxide gas after the collision with the process substrate SUB, no carbon dioxide particles remain as foreign matter on the process substrate SUB.

FIG. 7 is a view which schematically shows the structure of the wash gun GN which is applied to the dry wash process of the embodiment.

The wash gun GN includes a first space SP1 in which compressed, liquefied carbon dioxide is introduced, and a second space SP2 communicating with the first space SP1 via an orifice OF. The second space SP2 communicates with the nozzle NZ. If the liquefied carbon dioxide, which has been introduced in the first space SP1, is jetted through the orifice OF, part of the liquefied carbon dioxide is gasified, while the temperature sharply drops due to absorption of evaporation heat and other part of the liquefied carbon dioxide is solidified. Thus, in the second space SP2, the solid carbon dioxide particles and carbon dioxide gas are mixedly present. The carbon dioxide particles, together with the carbon dioxide gas that is an inert gas, are jetted from the nozzle NZ as a white mist.

FIG. 8 is a schematic view for describing the dry wash process of the embodiment.

A counter-electrode CE, which is formed on the process substrate SUB, extends in a first direction D1 and a second direction D2. Facing the surface SF of the process substrate SUB on which the counter-electrode CE is already formed, the wash gun GN is reciprocally scanned, while jetting particulate matter. While the wash gun GN is reciprocally scanned, the wash gun GN is successively moved in the second direction D2 from above to below in FIG. 8. After the wash gun GN has been moved downward in the second direction D2, relative to the surface SF of the process substrate SUB, the wash gun GN is, once again, reciprocally scanned in the first direction D1 and successively moved in the second direction D2 from below to above in FIG. 8.

In the example shown in FIG. 8, the wash gun GN is scanned. Alternatively, the process substrate SUB may be moved with the position of the wash gun GN is being fixed, or both the wash gun GN and process substrate SUB may be moved. The method for washing the process substrate SUB is not limited to the above-described examples.

As has been described above, according to the present embodiment, it is possible to provide the organic EL device and the manufacturing method thereof, which can suppress degradation due to moisture.

In the embodiment, the organic EL display device has been described as the organic EL device. However, the organic EL device is applicable to organic EL illuminations, organic EL printer heads, etc.

The method of dry wash, which is applicable to the embodiment, is not limited to the CO₂ wash. Other methods may be used if dry wash, which can remove foreign matter on the order of μm or more, without using water, is performed by jetting the particulate matter PT which is sublimated after colliding with the process substrate SUB. Preferably, the size of the particulate matter PT, which is jetted, should be equal to the size of foreign matter that is to be removed, and should be about 1 to 10 μm. In addition, the particulate matter PT should preferably be a substance (e.g. nitrogen or helium) which is sublimated with the passing of several seconds after the jet (e.g. five seconds after the jet) in at temperatures of the washing environment (e.g. room temperature).

In the present embodiment, the protection film 115 of the array substrate 100 and the sealing substrate 200 may be spaced apart, or a resin layer, for instance, may be filled between the protection film 115 and the sealing substrate 200.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

In the embodiments, the organic EL display device has been described as the organic EL device. However, the organic EL device is applicable to organic EL illuminations, organic EL printer heads, etc.

What is claimed is:

1. An organic EL device comprising:
an insulating substrate;
a pixel electrode disposed above the insulating substrate;
an organic layer disposed on the pixel electrode;
a counter-electrode disposed on the organic layer;
at least one of a first recess portion in which the organic layer and the counter-electrode are missing on the pixel electrode, and a second recess portion in which the counter-electrode is missing on the organic layer; and
a protection film covering the counter-electrode and said at least one of the first recess portion and the second recess portion.

2. The organic EL device according to claim 1, wherein the protection film is in contact with a top surface of the pixel electrode in the first recess portion.

3. The organic EL device according to claim 1, wherein the protection film is in contact with a top surface of the organic layer in the second recess portion.

4. The organic EL device according to claim 1, wherein the protection film is formed of an inorganic compound.

5. The organic EL device according to claim 1, further comprising an emission part in which the pixel electrode, the organic layer and the counter-electrode are stacked, and a non-emission part including said at least one of the first recess portion and the second recess portion.

6. The organic EL device according to claim 5, wherein an area of the non-emission part is less than 10% when an area of the emission part is set to be 100%.

7. An organic EL device comprising:
an insulating substrate;
an organic EL element disposed above the insulating substrate and including an emission part which emits light, and a recess part which emits no light and has an area of less than 10% when an area of the emission part is set to be 100%; and
a protection film covering the organic EL element.

8. The organic EL device according to claim 7, wherein the emission part includes a pixel electrode disposed above the insulating substrate, an organic layer disposed on the pixel electrode, and a counter-electrode disposed on the organic layer.

9. The organic EL device according to claim 7, wherein the recess part includes at least one of a first recess portion in which the organic layer and the counter-electrode are missing on the pixel electrode, and a second recess portion in which the counter-electrode is missing on the organic layer.

10. The organic EL device according to claim 9, wherein the protection film is in contact with a top surface of the pixel electrode in the first recess portion.

11. The organic EL device according to claim 9, wherein the protection film is in contact with a top surface of the organic layer in the second recess portion.

12. The organic EL device according to claim 7, wherein the protection film is formed of an inorganic compound.

13. A manufacturing method of an organic EL device, comprising:
forming a pixel electrode above an insulating substrate;
forming an organic layer on the pixel electrode;
forming a counter-electrode on the organic layer; and
performing dry wash which jets toward a surface of a process substrate, on which the counter-electrode is already formed, particulate matter which is sublimated after colliding with the surface of the process substrate.

14. The manufacturing method of an organic EL device, according to claim 13, wherein the dry wash is performed in an inactive atmosphere.

15. The manufacturing method of an organic EL device, according to claim 13, wherein the particulate matter is jetted together with an inert gas.

16. The manufacturing method of an organic EL device, according to claim 13, wherein the particulate matter is carbon dioxide particles in which carbon dioxide is coagulated.

17. The manufacturing method of an organic EL device, according to claim 13, wherein the dry wash is performed while the process substrate is being de-electrified by an ionizer.

18. The manufacturing method of an organic EL device, according to claim 13, wherein a direction, in which the particulate matter is jetted toward the process substrate is a direction inclined to a normal line of the process substrate.

19. The manufacturing method of an organic EL device, according to claim 13, wherein a protection film covering the surface of the process substrate is formed after the dry wash.

20. The manufacturing method of an organic EL device, according to claim 19, wherein the protection film is formed of an inorganic compound.
